(19) United States
(12) Patent Application Publication
(10) Pub. No.: US 2014/0117815 A1
(43) Pub. Date: May 1, 2014

(54) TEMPERATURE COMPENSATED RESONATOR DEVICE HAVING LOW TRIM SENSITIVY AND METHOD OF FABRICATING THE SAME

(71) Applicant: AVAGO TECHNOLOGIES GENERAL IP (SINGAPORE) PTE., Singapore (SG)

(72) Inventors: Zhiqiang BI, Fort Collins, CO (US); Richard C. Ruby, Menlo Park, CA (US)

(73) Assignee: Avago Technologies General IP (Singapore) Pte. Ltd, Singapore (SG)

(21) Appl. No.: 13/661,669

(22) Filed: Oct. 26, 2012

(51) Int. Cl. H03H 9/17; H01L 41/22; H03H 9/205

(52) U.S. Cl. 310/346; 438/50; 257/E21.002

(57) ABSTRACT

A temperature compensated bulk acoustic wave (BAW) resonator device has low trim sensitivity for providing an accurate resonant frequency. The BAW resonator device includes a first electrode deposited on a substrate, a piezoelectric layer deposited on the first electrode, a second electrode deposited on the piezoelectric layer, and a mirror pair deposited on the second electrode. At least one of the first electrode and the second electrode includes an electrode layer, and a temperature compensating layer configured to compensate for a temperature coefficient of at least the piezoelectric layer.

### BACKGROUND

Transducers generally convert electrical signals to mechanical signals or vibrations, and/or mechanical signals or vibrations to electrical signals. Acoustic transducers, in particular, convert electrical signals to acoustic signals (sound waves) and convert received acoustic waves to electrical signals via inverse and direct piezoelectric effect. Acoustic transducers generally include acoustic resonators, such as bulk acoustic wave (BAW) resonators and surface acoustic wave (SAW) resonators, and may be used in a wide variety of electronic applications, such as cellular telephones, personal digital assistants (PDAs), electronic gaming devices, laptop computers and other portable communications devices. Examples of BAW resonators include thin film bulk acoustic resonators (FBARs), which require air interfaces on either side of a vibrating resonator, and solidly mounted resonators (SMRs), which are mounted above an acoustic mirror stack.

It is desirable to use acoustic resonators in oscillators, such as voltage controlled oscillators (VCOs) or clock sources, in radio frequency (RF) systems, for example. Conventional oscillators typically use quartz crystal resonators, which provide high frequency accuracy, low frequency drift with temperature, and low noise. However, quartz crystal resonators are relatively large in size, and they have not scaled down in physical size to match current density requirements of many electrical circuits. Also, the frequency range is limited to hundreds of MHz. In comparison, acoustic resonators, such as conventional FBARs, are much smaller than quartz crystal resonators. More significantly, FBARS are capable of resonating at very high frequencies from 400 MHz to above 5 GHz, which is particularly useful in many communication applications. Also, FBARs can be mass-produced in wafer level, in which tens of thousands of FBARs may be fabricated at one time, by using processes compatible with semiconductor fabrication processes. However, they do not provide sufficient accuracy with regard to the required oscillating frequency (e.g., resonant frequency), and experience relatively high frequency drift in response to temperature variations, as compared to typical quartz crystal resonators.

FBARs are fabricated as part of a wafer, and then separated into individual dies during the manufacturing process. Frequency of conventional FBARs tends to vary across the wafer. For example, conventional FBARs are very sensitive to frequency trimming (or wafer trimming), which is a process used to remove extremely small amounts of material from a top-most layer of the wafer in order to decrease thickness, thereby fine tuning the resonant frequencies of the FBARs while still part of the wafer. The high trimming sensitivity results in lack of frequency uniformity across the wafer, and further causes difficulty in providing the precise resonant frequency. For example, frequency uniformity at the wafer level typically exceeds about 300 parts per million (PPM) at one sigma, which is insufficient for FBARs to replace quartz crystal oscillators in many practical applications.

Accordingly, an acoustic resonator, such as an FBAR, is needed with very low sensitivity for frequency trimming, particularly at the wafer level, as well as good temperature compensation characteristics. This would enable acoustic resonators to be used reliably in oscillators in a variety of applications.

### SUMMARY

According to a representative embodiment, a temperature compensated bulk acoustic wave (BAW) resonator device, having low trim sensitivity for providing an accurate resonant frequency, includes a first electrode deposited on a substrate, a piezoelectric layer deposited on the first electrode, a second electrode deposited on the piezoelectric layer, and an acoustic mirror pair deposited on the second electrode. At least one of the first electrode and the second electrode includes an electrode layer, and a temperature compensating layer configured to compensate for a temperature coefficient of at least the piezoelectric layer.

According to another representative embodiment, a wafer having multiple BAW resonator devices, separable from one another by cutting the wafer, includes a first electrode layer disposed on a substrate, a piezoelectric layer disposed on the first electrode layer, a second electrode layer disposed on the piezoelectric layer, a low acoustic impedance layer disposed on the second electrode layer, a high acoustic impedance layer disposed on the low acoustic impedance layer, and a temperature compensating layer buried in at least one of the first electrode layer and the second electrode layer, the temperature compensation layer having a positive temperature coefficient. The temperature compensating layer enables the BAW resonator devices to provide substantially uniform temperature compensation. The low and high acoustic impedance layers enable the wafer to have low sensitivity to frequency trimming, such that the BAW resonator devices provide substantially uniform resonant frequencies.

According to another representative embodiment, a method is provided for fabricating multiple BAW resonator devices having low sensitivity to frequency trimming and providing substantially uniform temperature compensation. The method includes forming a first electrode layer on a semiconductor substrate on a wafer, the first electrode comprising a temperature compensating layer; forming a piezoelectric layer over the first electrode; forming a second electrode layer over the piezoelectric layer; forming an acoustic mirror pair layer over the second electrode, the mirror pair including a low acoustic impedance layer and a high acoustic impedance layer; forming a passivation layer over the mirror pair layer; and frequency trimming at least one of the low acoustic impedance layer, the high acoustic impedance layer and the passivation layer to tune a resonant frequency of the BAW resonator devices.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. Where technical features in the figures, detailed description or any claim are followed by references signs, the reference signs have been included for the sole purpose of increasing the intelligibility of the figures, detailed description, and/or claims. Accordingly, neither the reference signs nor their absence are intended to have any limiting effect on the scope of any claim elements. In the figures, each identical or nearly identical component that is illustrated in various figures is represented by a like numeral. For purposes of clarity, not every component may be labeled in every figure. In the figures:

FIG. 1 is a cross-sectional view of a resonator device, according to a representative embodiment;

FIG. 2 is a cross-sectional view of a resonator device, according to a representative embodiment;

FIG. 3 is a cross-sectional view of a wafer including multiple resonator devices, according to a representative embodiment;

FIG. 4 is a flow diagram showing fabrication of the wafer depicted in FIG. 3, according to a representative embodiment; and

FIG. 5 is a comparative graph depicting comparative changes in set-on resonant frequencies of resonator devices.

### DETAILED DESCRIPTION

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the illustrative embodiments. Such methods and apparatuses are clearly within the scope of the present teachings.

Representative embodiments are directed to a BAW resonator structure that provides advantages over known BAW resonators. According to a representative embodiment, a BAW resonator includes an FBAR having an acoustic mirror pair included in a multi-layer film stack. According to another representative embodiment, the FBAR may further include a passivation layer over the acoustic mirror pair. The addition of the acoustic mirror pair may significantly alter the dispersion of the BAW resonator and allow reduction in, or elimination of, the losses below the series resonant frequency. In addition, the addition of the acoustic mirror pair provides significantly better frequency trimming tolerance than known BAW resonators, whether trimming the high impedance layers of the acoustic mirror pair or trimming the passivation layer. This allows manufacture of resonators with accurate frequency. Also, according to a representative embodiment, the BAW resonator further includes a temperature compensating layer in at least one of two electrodes, providing decreased sensitivity of frequency due to changes in temperature. Thus, the BAW resonator, according to the various embodiments, effectively provides a zero drift resonator (ZDR), with respect to temperature, capable of acting as a compact, highly reliable resonators, e.g., used in a clock source or a local frequency oscillation, replacing quartz crystal resonators. The BAW resonator may likewise be used for any other capability benefitting from ZDR functionality, such as filtering and duplexer filtering, for example.

Certain aspects of the BAW resonators of representative embodiments may be fabricated according to the teachings of commonly owned U.S. Pat. Nos. 5,587,620; 5,873,153; 6,384,697; 6,507,983; and 7,275,292 to Ruby et al.; and 6,828,713 to Bradley et al. These patents are hereby incorporated by reference. It is emphasized that the methods and materials described in these patents are representative and other methods of fabrication and materials within the purview of one of ordinary skill in the art are contemplated.

It is to be appreciated that embodiments of the methods and apparatus discussed herein are not limited in application to the details of construction and the arrangement of components set forth in the following description or illustrated in the accompanying figures. The methods and apparatus are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments. Like reference numerals in the figures refer to like elements.

Also, the phraseology and terminology used herein is for the purpose of description and should not be regarded as limiting. Any references to embodiments or elements or acts of the systems and methods herein referred to in the singular may also embrace embodiments including a plurality of these elements, and any references in plural to any embodiment or element or act herein may also embrace embodiments including only a single element. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, and upper and lower are intended for convenience of description, not to limit the present systems and methods or their components to any one positional or spatial orientation. The terms “a” or “an”, as used herein are defined as one or more than one. The term “plurality” as used herein is defined as two or more than two.

As used in the specification and appended claims, and in addition to their ordinary meanings, the terms “substantial” or “substantially” mean to with acceptable limits or degree. For example, “substantially cancelled” means that one skilled in the art would consider the cancellation to be acceptable. Also, as used in the specification and the appended claims and in addition to its ordinary meaning, the terms “about” and “approximately” mean to within an acceptable limit or amount to one having ordinary skill in the art. For example, “approximately the same” means that one of ordinary skill in the art would consider the items being compared to be the same.

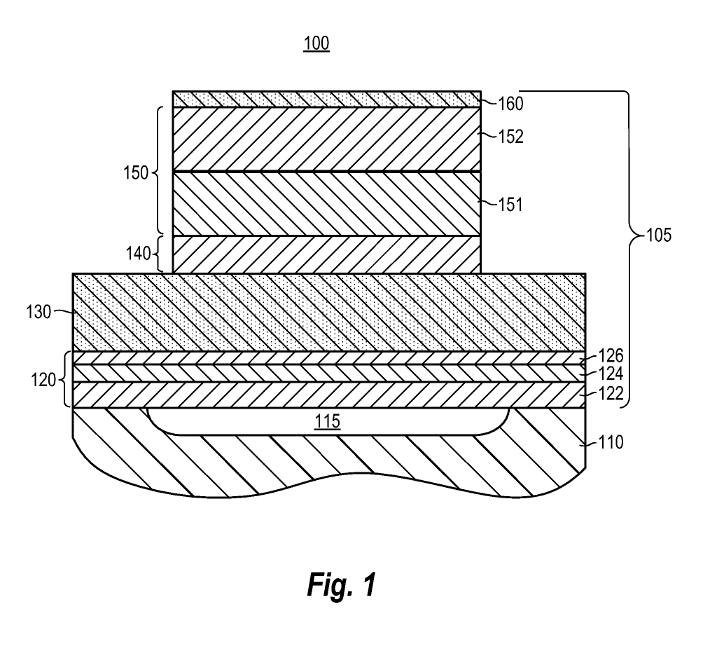

FIG. 1 is a cross-sectional view of an acoustic resonator device, which includes a mirror pair and an electrode having a temperature compensating layer, according to a representative embodiment.

Referring to FIG. 1, illustrative resonator device 100 includes (acoustic) multi-layer film stack 105 formed on substrate 110. The resonator device 100 is a BAW resonator device, and more particularly, an FBAR in the depicted illustrative configuration. The substrate 110 may be formed of various types of semiconductor materials compatible with semiconductor processes, such as silicon (Si), gallium arsenide (GaAs), indium phosphide (InP), or the like, which is useful for integrating connections and electronics, thus reducing size and cost. In the depicted embodiment, the substrate 110 includes a cavity 115 formed beneath the multi-layer film stack 105 to provide acoustic isolation, such that the multi-layer film stack 105 is suspended over an air space to enable mechanical movement.

In alternative embodiments, the substrate 110 may be formed with no cavity 115, for example, using SMR technology. For example, the multi-layer film stack 105 may be formed over an acoustic mirror or a Bragg Reflector (not shown), having alternating layers of high and low acoustic impedance materials, formed in the substrate 110. Each of the layers is approximately one quarter-wavelength thick at the acoustic wavelength. An acoustic reflector may be fabricated according to various techniques, an example of which is described in U.S. Pat. No. 7,358,831 to Larson, III, et al., which is hereby incorporated by reference.

The multi-layer film stack 105 includes piezoelectric layer 130 formed between first electrode 120 and second electrode 140. The first electrode 120 includes multiple layers, and is referred to herein as a composite electrode. In various embodiments, the composite first electrode 120 includes a base electrode layer 122, a temperature compensating layer 124, e.g., an oxide layer, and a conductive interposer layer 126 stacked sequentially on the substrate 110. The base electrode layer 122 and the conductive interposer layer 126 are formed of electrically conductive materials, such as various metals compatible with semiconductor processes, including tungsten (W), molybdenum (Mo), aluminum (Al), platinum (Pt), ruthenium (Ru), niobium (Nb), or hafnium (Hf), for example.

In various embodiments, the base electrode layer 122 and the conductive interposer layer 126 are formed of different conductive materials, where the base electrode layer 122 is formed of a material having relatively lower conductivity and relatively higher acoustic impedance, and the conductive interposer layer 126 is formed of a material having relatively higher conductivity and relatively lower acoustic impedance. For example, the base electrode layer 122 may be formed of W and the conductive interposer layer 126 may be formed of Mo, although other materials and/or combinations of materials may be used without departing from the scope of the present teachings. Further, in various embodiments, the base electrode layer 122 and the conductive interposer layer 126 may be formed of the same conductive material, without departing from the scope of the present teachings.

The temperature compensating layer 124 is formed between the base electrode layer 122 and the conductive interposer layer 126. The temperature compensating layer 124 is therefore separated or isolated from the piezoelectric layer 130 by the conductive interposer layer 126. The temperature compensating layer 124 may be formed of various materials compatible with semiconductor processes, including boron silicate glass (BSG), silicon dioxide (SiO₂), chromium (Cr) or tellurium oxide (TeO₍ₓ₎), for example, which have positive temperature coefficients. The positive temperature coefficient of the temperature compensating layer 124 offsets negative temperature coefficients of other materials in the multi-layer film stack 105, including the piezoelectric layer 130, the second electrode 140, and the base electrode layer 122 and the conductive interposer layer 126 of the composite first electrode 120. In addition, the conductive interposer layer 126 provides a barrier that prevents oxygen in the temperature compensating layer 124 from diffusing into the piezoelectric layer 130, preventing contamination of the piezoelectric layer 130. An example of adding a temperature compensating layer to one or both electrodes of a resonator device is described in U.S. Patent App. Pub. No. 2011/0266925 to Ruby et al., published on Nov. 3, 2011, which is hereby incorporated by reference.

The piezoelectric layer 130 is formed on the top surface of the conductive interposer layer 126. The piezoelectric layer 130 may be formed of a thin film piezoelectric compatible with semiconductor processes, such as aluminum nitride (AlN), zinc oxide (ZnO), lead zirconium titanate (PZT), or the like. The thickness of the piezoelectric layer 130 may range from about 1000 Angstroms (Å) to about 100,000 Å, for example, although the thickness may vary to provide unique benefits for any particular situation or to meet application specific design requirements of various implementations, as would be apparent to one of ordinary skill in the art. In an embodiment, the piezoelectric layer 130 may be formed on a seed layer (not shown) disposed over an upper surface the composite first electrode 120. For example, the seed layer may be formed of Al to foster growth of an AlN piezoelectric layer 130. The seed layer may have a thickness in the range of about 50 Å to about 5000 Å, for example.

The second electrode 140 is formed on the top surface of the piezoelectric layer 130. The second electrode 140 is formed of an electrically conductive material compatible with semiconductor processes, such as Mo, W, Al, Pt, Ru, Nb, Hf, or the like. In an embodiment, the second electrode 140 is formed of the same material as the base electrode layer 122 of the first electrode 120. However, in various embodiments, the second electrode 140 may be formed of the same material as only the conductive interposer layer 126; the second electrode 140, the conductive interposer layer 126 and the base electrode layer 122 may all be formed of the same material; or the second electrode 140 may be formed of a different material than both the conductive interposer layer 126 and the base electrode layer 122, without departing from the scope of the present teachings. The first and second electrodes 120 and 140 are electrically connected to external circuitry via contact pads (not shown), which may be formed of a conductive material, such as gold, gold-tin alloy or the like.

An acoustic mirror pair 150 is formed on a top surface of the second electrode 140. The acoustic mirror pair 150 includes a low acoustic impedance layer 151 and a high acoustic impedance layer 152. The low acoustic impedance layer 151 is formed of material having relatively low acoustic impedance, such as SiO₂, AlN, silicon carbide (SiC), BSG, silicon nitride (SiN), polysilicon, and the like. The high acoustic impedance layer 152 is formed of material having relatively high acoustic impedance, such as tungsten (W), tungsten oxide (WO₍ₓ₎), Mo, Pt, Ru or other high density metal or metal compound, or non-metal materials, for example. Those skilled in the art will appreciate, however, that other suitable materials may be used for the acoustic mirror pair 150, without departing from the scope of the present teachings. Also, in the depicted embodiment, the resonator device 100 includes only a single acoustic mirror pair 150 as an acoustic reflector. However, in other embodiments, one or more additional acoustic mirror layers may be added, where adjacent layers are formed of alternating low and high acoustic impedance materials, without departing from the scope of the present teachings. An example of adding an acoustic mirror to a resonator device is described in U.S. Patent App. Pub. No. 2011/0121916 to Barber et al., published on May 26, 2011, which is hereby incorporated by reference.

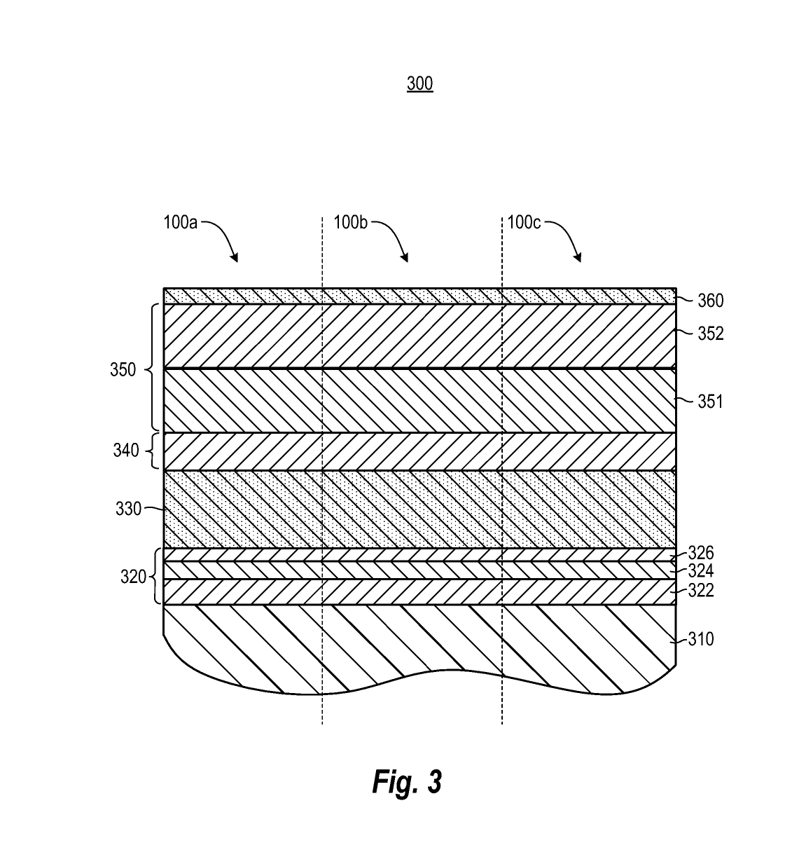

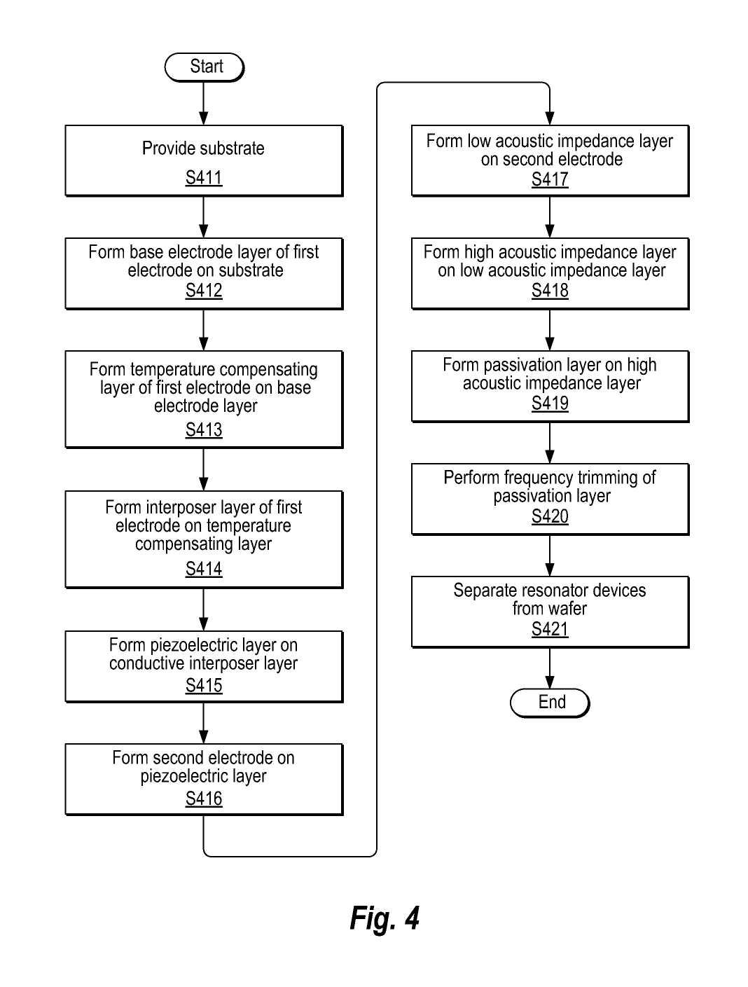

A passivation layer 160 is formed on a top surface of the acoustic mirror pair 150. The passiviation layer 160 may be formed of various comparatively low acoustic impedance materials, including AlN, SiC, BSG, SiO₂, SiN, polysilicon, and the like. The thickness of the passivation layer 160 is sufficient to insulate all layers of the multi-layer film stack 105 from the environment, including protection from moisture, corrosives, contaminants, debris and the like. In addition, the passivation layer 160 is initially applied during the fabrication process at a thickness slightly larger than ultimately required, so that the resonant frequency of the resonator device 100 may be tuned to the desired frequency by subsequent frequency trimming of the passivation layer 160. The frequency trimming takes place while the resonator device 100 is still part of a wafer, which contains multiple resonator devices, as discussed below with reference to FIGS. 3 and 4. For example, the passivation layer 160 may be trimmed at an accuracy of about plus/minus 10 Å until the initial set-on resonant frequency of the resonator device 100 (along with the other resonator devices of the wafer) is established.

In an alternative embodiment, no passivation layer 160 is added to the acoustic mirror pair 150, in which case frequency trimming is performed on the high acoustic impedance layer 152 and/or the low acoustic impedance layer 151. Also, in various embodiments, one or more layers other than the top-most layer may be subjected to frequency trimming. For example, the high acoustic impedance layer 152 may be applied more thickly and then frequency trimmed before application of the passivation layer 160 (which may or may not also be frequency trimmed). Likewise, the low acoustic impedance layer 151 may be applied more thickly and then frequency trimmed before application of the high acoustic impedance layer 152 and the passivation layer 160 (each of which may or may not also be frequency trimmed).

Frequency trimming the passivation layer 160 applied to the acoustic mirror pair 150 improves trim sensitivity (i.e., reduces trim sensitivity) by more than about 60 times over conventional frequency trimming (which is performed on a passivation layer applied directly to the top electrode). Accordingly, the acoustic resonator 100 may by provided with a very accurate set-on resonant frequency. Further, the temperature compensating layer 124 enables the acoustic resonator 100 to maintain the resonant frequency over a broad range of temperature variations. These characteristics enable use of the acoustic resonator 100 in an oscillator. For example, an oscillator in an RF system, used as a clock source or a local oscillator for down-converting and/or removing carrier frequencies, for example, typically requires frequency accuracy within a range of about ±50 ppm, which may be provided by the configuration of the acoustic resonator 100.

In the illustrative configuration of FIG. 1, with respect to the first electrode 120, the base electrode layer 122 may be formed at a thickness of about 3700 Å, the temperature compensating layer 124 may be formed at a thickness of about 1250 Å, and the interposer layer 126 may be formed at a thickness of about 350 Å. The second electrode 140 may be formed at a thickness of about 4070 Å. Each of the base electrode layer 122, the interposer layer 126, and the second electrode 140 may be formed of Mo, and the temperature compensating layer 124 may be formed using a thin film of SiO₂, which provides a large positive temperature coefficient, for example. The base electrode layer 122 may be formed on a seed layer (not shown) of AlN, for example, having a thickness of about 300 Å. The piezoelectric layer 130 may be formed at a thickness of about 12,167 Å using a thin film of AlN. The low acoustic impedance mirror layer 151 may be is formed of SiO₂ at a thickness of about 9900 Å, and the high acoustic impedance layer 152 may be is formed of WO₂ at a thickness of about 8800 Å. The passivation layer 160 may be formed at a thickness of about 2,400 Å using a thin film of AlN. Of course, the foregoing dimensions and materials are illustrative, and various alternative configurations of the various layers may be incorporated without departing from the spirit of the present teachings.

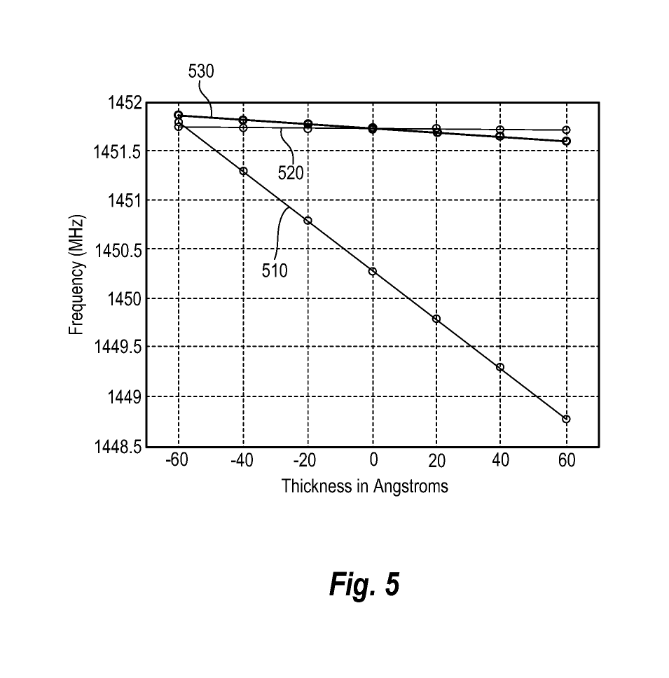

FIG. 5 is a comparative graph depicting changes in set-on resonant frequency of resonator device 100, according to a representative embodiment, in which the layers have the illustrative dimensions and materials mentioned above. More particularly, FIG. 5 demonstrates the low trim sensitivity of the resonator device 100, as compared to a conventional resonator device.

Referring to FIG. 5, the vertical axis shows resonant frequency of a resonator device and the horizontal axis shows variations in thickness of a trimmed layer of the resonator device, e.g., in response to a frequency trimming process. Curve 510 corresponds to a conventional resonator device, in which frequency trimming is performed on a passivation layer applied directly on the top electrode layer. Curve 520 corresponds to the resonator device 100, in which frequency trimming is performed on the passivation layer 160 (e.g., AlN) applied directly to the acoustic mirror pair 150. Curve 530 corresponds to a modification of the resonator device 100, in which frequency trimming is performed on the high acoustic impedance layer 152 (e.g., W) of the acoustic mirror pair 150.

Curve 510 shows that relatively small changes in thickness from the frequency trimming process result in large variations in the resonant frequency of the conventional resonator device. That is, over a range of about 120 Å (from about −60 Å to about +60 Å), the resonant frequency of the conventional resonator device drops about 3 MHz (from about 1451.7 MHz to about 1448.7 MHz), resulting in approximately 0.0250 MHz/Å trim sensitivity. In comparison, curve 520 shows very little change (less than about 0.05 MHz) over the same range of about 120 Å, resulting in approximately 0.0004 MHz/Å trim sensitivity. Curve 530 similarly shows very little change (less than about 0.3 MHz) over the same range of about 120 Å, resulting in approximately 0.0025 MHz/Å trim sensitivity. FIG. 5 thus indicates that trim sensitivity of the resonator device 100, according to curve 520 in particular, is more than 60 times better than that of the conventional resonator device. Stated differently, the trim sensitivity indicated by curve 510 of the conventional resonator device is about 16.0 ppm/Å, while the trim sensitivity of the illustrative resonator device 100 indicated by curve 520 is only about 0.25 ppm/Å and indicated by curve 530 is only about 1.5 ppm/Å.

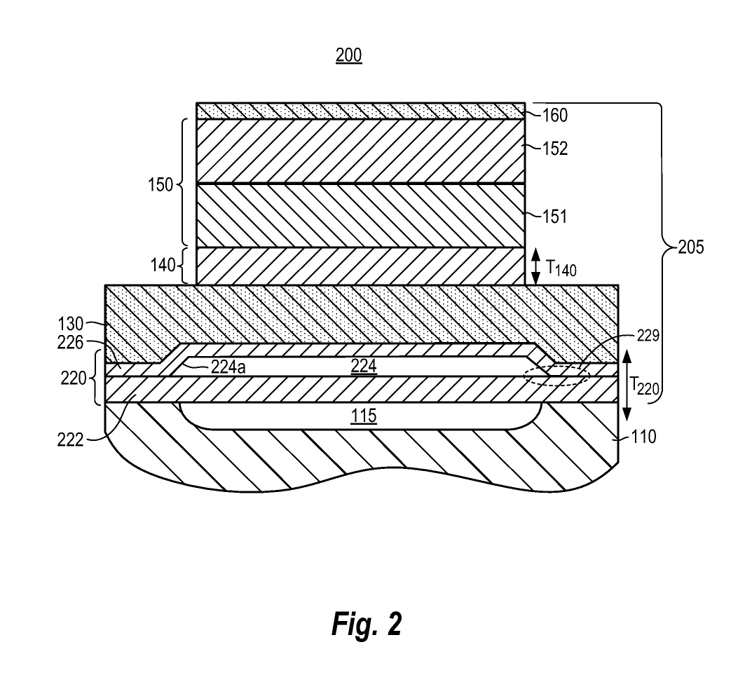

FIG. 2 is a cross-sectional view of an acoustic resonator device, which includes an acoustic mirror pair and a bottom electrode having a buried temperature compensating layer, according to a representative embodiment.

Referring to FIG. 2, illustrative resonator device 200 includes (acoustic) multi-layer film stack 205 formed on substrate 110. The multi-layer film stack 205 includes piezoelectric layer 130 formed between first electrode 220 and second electrode 140. Similar to the first electrode 120 of FIG. 1, the first electrode 220 is a composite electrode including multiple layers. In various embodiments, the composite first electrode 220 includes a base electrode layer 222, a buried temperature compensating layer 224, and a conductive interposer layer 226 stacked sequentially on the substrate 110, which may formed of the same materials discussed above with respect to the base electrode layer 122, the temperature compensating layer 124 and the interposer layer 126, for example. The temperature compensating layer 224 is buried in that at least a portion of the temperature compensating layer 224 is surrounded by the base electrode layer 222 and the conductive interposer layer 226. Like reference numerals in FIGS. 1 and 2 refer to like elements, and therefore corresponding descriptions of like elements will not be repeated.

The temperature compensating layer 224 may be encapsulated or sealed between the conductive interposer layer 226 and the base electrode layer 222, meaning that it is surrounded on all sides by the conductive interposer layer 226 and the base electrode layer 222. However, the temperature compensating layer 224 may not be sealed or only partially sealed, without departing from the scope of the present teachings. As shown, the temperature compensating layer 224 does not extend the full width of the multi-layer film stack 205. Thus, the conductive interposer layer 226, which is formed on the top and side surfaces of the temperature compensating layer 224, contacts the top surface of the base electrode layer 222, as indicated for example by reference number 229. Therefore, a DC electrical connection is formed between the conductive interposer layer 226 and the base electrode layer 222. By DC electrically connecting with the base electrode layer 222, the conductive interposer layer 226 effectively “shorts” out a capacitive component of the temperature compensating layer 224, thus increasing a coupling coefficient (kₜ²) of the resonator device 200.

Also, in the depicted embodiment, the temperature compensating layer 224 has tapered edges 224a, which enhance the DC electrical connection between the conductive interposer layer 226 and the base electrode layer 222. In addition, the tapered edges 224a enhance the mechanical connection between the conductive interposer layer 226 and the base electrode layer 222, which improves the sealing quality, e.g., for preventing oxygen in the temperature compensating layer 224 from diffusing into the piezoelectric layer 130. In alternative embodiments, the edges of the temperature compensating layer 224 are not tapered, but may be substantially perpendicular to the top and bottom surfaces of the temperature compensating layer 224, for example, without departing from the scope of the present teachings.

In an embodiment, an overall first thickness T₂₂₀ of the first electrode 220 is substantially the same as an overall second thickness T₁₄₀ of the second electrode 140, as shown in FIG. 2. For example, the thickness of each of the first and second electrodes 220 and 140 may range from about 600 Å to about 30000 Å, although the thicknesses may vary to provide unique benefits for any particular situation or to meet application specific design requirements of various implementations, as would be apparent to one of ordinary skill in the art.

The multiple layers of the composite first electrode 220 have corresponding thicknesses. For example, the thickness of the base electrode layer 222 may range from about 400 Å to about 29,900 Å, the thickness of the temperature compensating layer 224 may range from about 100 Å to about 5000 Å, and the thickness of the conductive interposer layer 226 may range from about 100 Å to about 10000 Å. Each of the layers of the composite first electrode 220 may be varied to produce different characteristics with respect to temperature coefficients and coupling coefficients, while the overall first thickness T₂₂₀ of the composite first electrode 220 remains substantially the same as the overall second thickness T₁₄₀ of the second electrode 140. For example, the thickness of the temperature compensating layer 224 may be varied to affect the overall temperature coefficient of the multi-layer film stack 205, and the relative thicknesses of the base electrode layer 222 and the conductive interposer layer 226 may be varied to affect the overall coupling coefficient of the resonator device 200.

In the example shown in FIG. 2, the thickness of the base electrode layer 222 is greater than the thickness of the conductive interposer layer 226, such that the buried temperature compensating layer 224 is in relatively close proximity to the piezoelectric layer 130. Alternatively, though, these thicknesses may be varied, thus “sinking” the buried temperature compensating layer 224 deeper into the composite first electrode 220 (and further away from the active piezoelectric layer 130). That is, the overall thickness T₂₂₀ of the first electrode 220 may remain substantially the same as the overall thickness T₁₄₀ of the second electrode 140, while the thickness of the conductive interposer layer 226 is increased, such that the temperature compensating layer 224 becomes buried more deeply, i.e., further “sinking,” within the composite first electrode 220. To compensate for the greater thickness of the conductive interposer layer 226, the thickness of the base electrode layer 222 is less, so that the overall first thickness T₂₂₀ of the composite first electrode 220 remains the same as the overall second thickness T₁₄₀ of the second electrode 140.

The thickness of the temperature compensating layer 224 can also be targeted to be thicker (e.g., as it is more deeply buried) to help maintain or minimize, the linear temperature coefficient. For example, when the temperature compensating layer 224 is buried in a deeper position within the first electrode 220, the temperature compensating layer 224 causes the coupling coefficient of the resonator device 200 to become relatively greater (at the expense of worsening temperature coefficient). In other words, by adjusting the depth of the temperature compensating layer 224, the coupling coefficient of the resonator device 200 may be optimized. Some of the degradation of the temperature coefficient can be “won back” by thickening the temperature compensating layer 224. Typically, there is an optimum between final temperature coefficient and coupling coefficient (kₜ²), depending on application.

Generally, the thickness and the location of the temperature compensating layer 224 inside the composite electrode 220 should be optimized, in order to maximize the coupling coefficient for an allowable linear temperature coefficient. This optimization may be accomplished, for example, by modeling an equivalent circuit of the multi-layer film stack 205 using a Mason model and adjusting the temperature compensating layer 224 by adding more material to the conductive interposer layer 226 and removing material from the base electrode layer 222, so the thickness of the composite first electrode 220 remains constant, as would be apparent to one of ordinary skill in the art. Although there is some degradation in the offsetting effects of the temperature coefficient by sinking the temperature compensating layer 224, the coupling coefficient of the resonator device 200 may be improved. An algorithm may be developed to optimize the depth of the temperature compensating layer 224 in the composite first electrode 220 in light of the trade-off between the temperature coefficient and the coupling coefficient, for example, using a multivariate optimization technique, such as a Simplex method, as would be apparent to one of ordinary skill in the art. In addition, the depth of the temperature compensating layer 224 may be limited by various constraints, such as minimum necessary coupling coefficient and maximum allowable temperature coefficient. Likewise, the thickness of the temperature compensating layer 224 may adjusted to provide the optimal coupling coefficient and a minimum overall temperature coefficient of the resonator device 200.

In the illustrative configuration of FIG. 2, the temperature compensating layer 224 may be formed at a thickness of about 1000 Å using a thin film of BSG (e.g., about two percent by weight boron), which provides a large positive temperature coefficient (e.g., up to about 350 ppm per deg C.). Each of the first thickness T₂₂₀ of the first electrode 220 and the second thickness T₁₄₀ of the second electrode 140 may be about 3000 Å. Also, the base electrode layer 222 of the first electrode 220 and the second electrode 140 may each be formed of Mo. The interposer layer 226 may also be made of Mo, and in this example would be between about 300 Å and about 600 Å. The piezoelectric layer 130 may be is formed at a thickness of about 11,000 Å using a thin film of AlN. The multi-layer film stack 205 with this illustrative configuration has a zero linear temperature coefficient value. Only a residual quadratic term is left (where beta is about −22 ppB per degree C²). However, the maximum coupling coefficient for the resonator device 200 of this configuration is only about 3.6 percent.

As mentioned above, in various embodiments, either or both of the bottom and top electrodes may include a buried temperature compensating layer, which are formed substantially the same as described with reference to FIG. 2. For example, the top electrode may be a composite electrode formed on a piezoelectric layer, such that a buried temperature compensating layer is formed between a base electrode layer and a conductive interposer layer, where the temperature compensating layer is separated from the piezoelectric layer by the conductive interposer layer.

FIG. 3 is a cross-sectional view of a wafer including multiple BAW resonator devices, according to a representative embodiment. According to various embodiments, the resonator devices may be fabricated using various techniques compatible with semiconductor processes. A non-limiting example of a fabrication process is discussed below with reference to FIG. 4, which is a flow diagram showing fabrication of the wafer depicted in FIG. 3, according to a representative embodiment.

Referring to FIG. 3, illustrative wafer 300 includes multiple BAW resonator devices, indicated by representative resonator devices 100a, 100b and 100c. Because the resonator devices 100a, 100b and 100c are on the same wafer 300, they have the same structure. For example, each of the resonator devices 100a, 100b and 100c has substantially the same structure as resonator device 100, discussed above with reference to FIG. 1, although other structures including at least one acoustic mirror pair and an electrode having a buried temperature compensating layer (e.g., representative resonator devices 200 discussed above) may be incorporated into the wafer 300 without departing from the scope of the present teachings.

In the depicted embodiment, the wafer 300 includes substrate 310. A first electrode layer 320 is formed on the substrate 310, where the first electrode layer 320 is a composite electrode including base electrode layer 322, buried temperature compensating layer 324, and conductive interposer layer 326. The buried temperature compensating layer 324 enables the resonator devices 100a, 100b and 100c to provide substantially uniform temperature compensation regardless of location on the wafer 300. A piezoelectric layer 330 is formed on the first electrode layer 320, and a second electrode layer 340 is formed on the piezoelectric layer 330.

An acoustic mirror pair layer 350 and a passivation layer 360 are stacked on the second electrode layer 340, where the acoustic mirror pair layer 350 includes low acoustic impedance layer 351 and high acoustic impedance layer 352. After formation of the wafer 300, the passivation layer 360 is trimmed to accurately obtain the desired resonant frequency for each of the resonator devices 100a, 100b and 100c, as discussed above. The low and high acoustic impedance layers 351 and 352 enable the wafer 300 to have low sensitivity to frequency trimming, as discussed above, such that the resonator devices 100a, 100b and 100c provide substantially uniform resonant frequencies regardless of location on the wafer 300. Of course, in alternative embodiments (e.g., not including the passivation layer 360), one or more of the low acoustic impedance layer 351 and high acoustic impedance layer 352 may be frequency trimmed, as discussed above. The wafer 300 may then be separated into the individual resonator devices 100a, 100b and 100c along the dashed lines, respectively, which are substantially the same as one another in terms of resonant frequency and temperature compensation characteristics.

Fabrication of the wafer 300 is now described with reference to the flow diagram of FIG. 4. Referring to FIGS. 3 and 4, substrate 310 is provided in block S411 and the base electrode layer 322 is formed on a top surface of the substrate 310 in block S412. The substrate 310 of the wafer 300 may be formed of various types of semiconductor materials compatible with semiconductor processes, such as Si, GaAs, InP, or the like. The base electrode layer 322 may be formed of an electrically conductive material, such as various metals compatible with semiconductor processes, including W, Mo, Al, Pt, Ru, Nb, or Hf, for example, although different materials and/or combinations of materials may be used, without departing from the scope of the present teachings. The base electrode layer 322 may be applied using spin-on, sputtering, evaporation, physical vapor deposition (PVD) or chemical vapor disposition (CVD) techniques, for example, although other application methods may be incorporated.

Notably, although not shown in FIG. 3, formation of cavities (e.g., cavity 115 in FIG. 1) corresponding to the resonator devices 100a, 100b and 100c may be carried out. For example, the cavities may be etched and initially filled with a sacrificial material, such as phosposilicate glass (PSG) or other release processes, such as polysilicon and xenon difluoride etchant, as would be apparent to one of ordinary skill in the art. The release of the sacrificial material to form the cavities is carried out using a suitable etchant, such as HF, after fabrication of the layers of the resonator devices 100a, 100b and 100c (e.g., after formation of the passivation layer 360). In alternative configurations, the cavities may pass through the substrate 310 to form backside openings, which may be formed by back side etching a bottom surface of the substrate 310. The back side etching may include a dry etch process, such as a Bosch process, for example, although various alternative techniques may be incorporated. The cavities may be formed by a number of known methods, examples of which are described in U.S. Pat. No. 6,384,697 to Ruby et al., which is hereby incorporated by reference.

Alternatively, the substrate 310 may include acoustic isolators (not shown), such as an acoustic mirrors or Bragg Reflectors, rather than the cavities, corresponding to the resonator devices 100a, 100b and 100c. Such acoustic isolators may be formed in the substrate 310 using any technique compatible with semiconductor processes, e.g., before applying the base electrode layer 322, as would be apparent to one of ordinary skill in the art. Examples fabricating acoustic mirrors for a resonator device are described in U.S. Patent App. Pub. No. 2011/0121916 to Barber et al., which is hereby incorporated by reference.

In block S413, temperature compensating layer 324 is formed on a top surface of the base electrode layer 322. In an embodiment, the temperature compensating layer 324 may be formed of various materials compatible with semiconductor processes, including BSG, SiO₂, Cr, or TeO₍ₓ₎, for example, which have positive temperature coefficients, although different materials and/or combinations of materials may be used without departing from the scope of the present teachings. The positive temperature coefficient of the temperature compensating layer 324 offsets negative temperature coefficients of other materials, including the piezoelectric layer 330, the second electrode 340, and the base electrode layer 322 and the conductive interposer layer 326 of the composite first electrode layer 320. The temperature compensating layer 324 may be applied using spin-on, sputtering, evaporation or CVD techniques, for example, although other application methods may be incorporated. Various illustrative techniques for forming temperature compensating layers are described, for example, in U.S. Pat. No. 7,561,009 to Larson, III, et al., which is hereby incorporated by reference.

In an embodiment in which the temperature compensating layer is sealed within the first electrode layer 320 with respect to each of the resonator devices 100a, 100b and 100c (e.g., as shown in FIG. 2), the temperature compensating layer 324 is segmented and etched to a desired size with respect to each of the resonator devices 100a, 100b and 100c, and the edges of each segmented portion of the temperature compensating layer 324 may be tapered. For example, a photoresist layer (not shown) may be applied to the top surface of the temperature compensating layer 324 and patterned to form a mask or photoresist pattern, using any photoresist patterning technique compatible with semiconductor processes, as would be apparent to one of ordinary skill in the art. The photoresist pattern may be formed by machining or by chemically etching the photoresist layer using photolithography, although various alternative techniques may be incorporated. Following etching of the temperature compensating layer 324, the photoresist pattern is removed, for example, by chemically releasing or etching using a wet etch process including HF etch solution, although the photoresist pattern may be removed by various other techniques, without departing from the scope of the present teachings.

Further, in various embodiments, to obtain the tapered edges (e.g., tapered edges 224a in FIG. 2), oxygen is leaked into the etcher used to etch the segmented portions of the temperature compensating layer 324. The oxide (and/or temperature chuck) causes the photoresist to erode more quickly at the edges of the patterned photo resist and to pull back slightly. This “thinning” of the resist forms a wedge shape profile that is then imprinted into the oxide underneath as the photoresist goes away. Generally, the wedge is created by adjusting the etch rate of resist relative to the etched material, as would be apparent to one of ordinary skill in the art. Meanwhile, further from the edges, there is sufficient photoresist coverage throughout the etch that the underlying oxide material is not touched. Of course, other methods of obtaining tapered edges may be incorporated without departing form the scope of the present teachings.

The conductive interposer layer 326 is formed on a top surface of the temperature compensating layer 324 in block S414. The conductive interposer layer 326 may be formed of an electrically conductive material, such as various metals compatible with semiconductor processes, including W, Mo, Al, Pt, Ru, Nb, or Hf, for example, although different materials and/or combinations of materials may be used, without departing from the scope of the present teachings. In addition, the conductive interposer layer 326 provides a barrier that prevents oxygen in the temperature compensating layer 324 from diffusing into the piezoelectric layer 330, preventing contamination of the piezoelectric layer 330. The conductive interposer layer 326 may be applied using spin-on, sputtering, evaporation, PVD or CVD techniques, for example, although other application methods may be incorporated.

In an alternative embodiment, an interim seed layer (not shown) is formed on the top surface of the temperature compensating layer 324. The interim seed layer may be formed of the same piezoelectric material as the piezoelectric layer 330, such as AlN, for example. The interim seed layer may be formed to a thickness of about 300 Å, for example, and further reduces or minimizes oxide diffusion from the temperature compensating layer 324 into the piezoelectric layer 330. Outer portions of the interim seed layer may be removed by etching (e.g., along with the etched portions of the temperature compensating layer 324, if any) to expose portions of the top surface of the base electrode layer 322, so that the base electrode layer 322 is able to make an electrical connection with the conductive interposer layer 326. In other words, after etching, the interim seed layer covers only the top surface of the temperature compensating layer 324, so that it is positioned between the temperature compensating layer 324 and the conductive interposer layer 326.

As discussed above, the base electrode layer 322 and the conductive interposer layer 326 may be formed of different conductive materials, where the base electrode layer 322 is formed of a material having relatively lower conductivity and relatively higher acoustic impedance, and the conductive interposer layer 326 is formed of a material having relatively higher conductivity and relatively lower acoustic impedance. For example, the base electrode layer 322 may be formed of W and the conductive interposer layer 326 may be formed of Mo, although other materials and/or combinations of materials may be used without departing from the scope of the present teachings. Of course, the base electrode layer 322 and the conductive interposer layer 326 may be formed of the same conductive material, without departing from the scope of the present teachings.

In block S415, the piezoelectric layer 330 is formed on a top surface of the conductive interposer layer 326, which is also the top surface of the first electrode layer 320. The piezoelectric layer 330 may be formed of a thin film piezoelectric compatible with semiconductor processes, such as AlN, ZnO, PZT, or the like, although different materials and/or combinations of materials may be used, as discussed above, without departing from the scope of the present teachings. The piezoelectric layer 330 may be applied using a sputtering technique, for example, although other application methods may be incorporated. For example, the piezoelectric layer 330 may be grown from a seed layer, as discussed above, according to various techniques compatible with semiconductor processes.

The second electrode 340 is formed on a top surface of the piezoelectric layer 330 in block S416. The second electrode 140 may be formed of an electrically conductive material, such as various metals compatible with semiconductor processes, including W, Mo, Al, Pt, Ru, Nb, or Hf, for example, although different materials and/or combinations of materials may be used, without departing from the scope of the present teachings. The second electrode 340 may be applied using spin-on, sputtering, evaporation, PVD or CVD techniques, for example, although other application methods may be incorporated.

In block S417, the low acoustic impedance layer 351 of the acoustic mirror pair 350 is formed (and optionally patterned) on a top surface of the second electrode 340. The low acoustic impedance mirror layer 351 is formed of material having relatively low acoustic impedance, such as SiO₂ or other oxide, for example, although different materials and/or combinations of materials may be used, without departing from the scope of the present teachings. In block S418, the high acoustic impedance layer 352 of the acoustic mirror pair 350 is formed (and optionally patterned) on a top surface of the low acoustic impedance mirror layer 351. The high acoustic impedance layer 352 is formed of material having relatively high acoustic impedance, such as W, WO₍ₓ₎, Mo, Pt, Ru or other high density metal or metal compound, for example, although different materials and/or combinations of materials may be used, without departing from the scope of the present teachings.

The passivation layer 360 is formed on the top surface of the high acoustic impedance layer 352 in block S419. The passivation layer 360 may be formed of various materials, including AlN, SiC, BSG, Si_{O2}, SiN, or polysilicon, for example, although different materials and/or combinations of materials may be used, without departing from the scope of the present teachings. The thickness of the passivation layer 160 is sufficient to insulate all layers of the respective multi-layer film stacks from the environment, including protection from moisture, corrosives, contaminants, debris and the like. In an alternative embodiment, no passivation layer 360 is added to the acoustic mirror pair 350, in which case frequency trimming (discussed below) may be performed on the high acoustic impedance layer 352 and/or the low acoustic impedance layer 351.

The passivation layer 360 is initially deposited more thickly than desired, which would result in a resonant frequency of each of the resonator devices 100a, 100b and 100c below the desired resonant frequency. Then, in block S420, frequency trimming is performed on the passivation layer 360, removing a determined thickness of the passivation layer 360 to tune the resonant frequency of each of the resonator devices 100a, 100b and 100c higher to the desired value. For example, removing thickness increases the resonant frequency. One example of a frequency trimming method, also referred to as wafer trimming, is discussed in U.S. Patent App. Pub. No. 2010/0068831 to Barber et al., published on Mar. 18, 2010, which is hereby incorporated by reference. The thickness of the material removed from the passivation layer 360 during the frequency trimming process determines the degree of frequency tuning The thickness of the material that must be removed to tune the resonant frequency by a certain amount depends, at least in part, on the desired resonant frequency. For example, the passivation layer 160 may be trimmed at an accuracy of about plus/minus 10 Å until the initial set-on resonant frequency is established.

Notably, for a conventional resonator device with a desired center resonant frequency of 5 GHz (also referred to as a 5 GHz resonator), for example, having a known FBAR or SMR structure, about 2.8 Å of material is typically removed from the top electrode layer to increase the center resonant frequency by 1 MHz. One Angstrom is the thickness of one atomic layer of material. Thus, at high frequencies, accurate frequency trimming is very difficult.

In an alternative embodiment, no passivation layer 360 is added to the acoustic mirror pair 350, as discussed above, in which case the frequency trimming is performed on the high acoustic impedance layer 352 and/or the low acoustic impedance layer 351. Also, in alternative embodiments, one or more layers other than the top-most layer (e.g., the passivation layer 360) may be applied more thickly and then frequency trimmed, in addition to or instead of frequency trimming the top-most layer. For example, the high acoustic impedance layer 352 may be applied more thickly (in block S418), and frequency trimmed before application of the passivation layer 360 (in block S419), which may or may not also be frequency trimmed. Similarly, the low acoustic impedance layer 351 may be applied more thickly and then frequency trimmed before application of the high acoustic impedance layer 352 and the passivation layer 360, each of which may or may not also be frequency trimmed. Also, when frequency trimming is performed on the high acoustic impedance layer 352 and/or the low acoustic impedance layer 351, application of the passivation layer 360 may be omitted.

In an embodiment, the frequency trimming of the passivation layer 160 is performed using ion beam trimming, for example. However, other suitable frequency trimming techniques may be incorporated without departing from the scope of the present teachings.

The wafer 300 is cut or separated, e.g., along the dashed lines in FIG. 3, in block S421 to form singulated dies (i.e., the resonator devices 100a, 100b and 100c). The wafer 300 may be separated using various techniques compatible with semiconductor fabrication processes, such as scribe and break, for example.

As discussed above, frequency trimming a resonator device having an acoustic mirror pair improves (i.e., reduces) trim sensitivity by more than about 60 times, for example, over conventional frequency trimming, which is performed on a passivation layer applied directly to the second electrode.

The resonator device and the fabrication process of the same according to various representative embodiments may provide significant improvements over conventional resonator devices and fabrication processes, including maintaining high coupling and good performance while providing significantly improved manufacturability, particularly at high frequencies. Having thus described several aspects of at least a representative embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. A temperature compensated bulk acoustic wave (BAW) resonator device having low trim sensitivity for providing an accurate resonant frequency, the device comprising:
a first electrode disposed on a substrate;
a piezoelectric layer disposed on the first electrode;
a second electrode disposed on the piezoelectric layer; and
an acoustic mirror pair disposed on the second electrode,
wherein at least one of the first electrode and the second electrode comprises:
an electrode layer; and
a temperature compensating layer configured to compensate for a temperature coefficient of at least the piezoelectric layer.

2. The device of claim 1, further comprising:
a passivation layer disposed on the acoustic mirror pair.

3. The device of claim 1, wherein the temperature compensating layer is a buried temperature compensating layer encapsulated within the electrode layer and a conductive interposer layer.

4. The device of claim 3, wherein the temperature compensating layer has tapered edges.

5. The device of claim 1, wherein the substrate defines a cavity formed beneath the first electrode.

6. The device of claim 1, wherein the substrate comprises an acoustic reflector formed beneath the first electrode.

7. The device of claim 1, wherein the acoustic mirror pair comprises:
a low acoustic impedance layer deposited on the second electrode; and
a high acoustic impedance layer deposited on the low acoustic impedance layer.

8. The device of claim 7, wherein the low acoustic impedance layer comprises silicon dioxide (SiO₂), aluminum nitride (AlN), silicon carbide (SiC), boron silicate glass (BSG), silicon nitride (SiN), polysilicon, and the like

9. The device of claim 8, wherein the high acoustic impedance layer comprises tungsten.

10. The device of claim 2, wherein the passivation layer and the piezoelectric material are formed of the same material.

11. A wafer having a plurality of bulk acoustic wave (BAW) resonator devices, separable from one another by cutting the wafer, the wafer comprising:
a first electrode layer disposed on a substrate;
a piezoelectric layer disposed on the first electrode layer;
a second electrode layer disposed on the piezoelectric layer;
a low acoustic impedance layer disposed on the second electrode layer;
a high acoustic impedance layer disposed on the low acoustic impedance layer; and
a temperature compensating layer buried in at least one of the first electrode layer and the second electrode layer, the temperature compensation layer having a positive temperature coefficient,
wherein the temperature compensating layer enables the plurality of devices to provide substantially uniform temperature compensation, and
wherein the low and high acoustic impedance layers enable the wafer to have low sensitivity to frequency trimming, such that the plurality of devices provide substantially uniform resonant frequencies.

12. The wafer of claim 11, further comprising:
a passivation layer disposed on the high acoustic impedance layer.

13. The wafer of claim 11, wherein the plurality of devices comprise a plurality of film bulk acoustic resonators (FBARs) or solidly mounted resonators (SMRs).

14. A method of fabricating a plurality of bulk acoustic wave (BAW) resonator devices having low sensitivity to frequency trimming and providing substantially uniform temperature compensation, the method comprising:
forming a first electrode layer on a semiconductor substrate on a wafer, the first electrode comprising a temperature compensating layer;
forming a piezoelectric layer over the first electrode;
forming a second electrode layer over the piezoelectric layer;
forming an acoustic mirror pair layer over the second electrode, the mirror pair comprising a low acoustic impedance layer and a high acoustic impedance layer;
forming a passivation layer over the mirror pair layer; and
frequency trimming at least one of the low acoustic impedance layer, the high acoustic impedance layer and the passivation layer to tune a resonant frequency of the plurality of BAW resonator devices.

15. The method of claim 14, further comprising:
separating the plurality of BAW resonator devices into singulated dies by cutting the wafer after frequency trimming the at least one of the low acoustic impedance layer, the high acoustic impedance layer and the passivation layer.

16. The method of claim 14, wherein forming the first electrode layer comprises:
forming a base electrode layer over the semiconductor substrate;
forming the buried temperature compensating layer over the base electrode layer; and
forming a conductive interposer layer over the buried temperature compensating layer.

17. The method of claim 16, further comprising:
forming a cavity between the base electrode layer electrode and the semiconductor substrate.

18. The method of claim 16, further comprising:
forming an acoustic reflector in the semiconductor substrate.
